(19) United States
(12) Patent Application Publication
(10) Pub. No.: US 2016/0192497 A1
(43) Pub. Date: Jun. 30, 2016

(54) ELECTRONIC COMPONENT MODULE AND MANUFACTURING METHOD THEREOF

(71) Applicant: SAMSUNG ELECTRO-MECHANICS CO., LTD., Suwon-Si (KR)

(72) Inventor: Myung Lim RYU, Suwon-Si (KR)

(73) Assignee: SAMSUNG ELECTRO-MECHANICS CO., LTD., Suwon-Si (KR)

(21) Appl. No.: 14/966,280

(22) Filed: Dec. 11, 2015

(30) Foreign Application Priority Data
Dec. 30, 2014 (KR) 10-2014-0193356

(51) Int. Cl. H05K 1/18; H05K 3/30; H05K 1/11

(52) U.S. Cl. CPC H05K 1/181; H05K 1/111; H05K 3/303; H05K 1/186

(57) ABSTRACT

An electronic component module including a first board; a plurality of first electronic components disposed on a first surface of the first board; a second board disposed on a second surface of the first board, opposite to the one surface, to form a cavity; a third board disposed on the second surface of the first board to divide the cavity into a plurality of regions; and a plurality of second electronic components disposed in the regions and disposed on the second surface of the first board.

### CROSS-REFERENCE TO RELATED APPLICATION

This application claims the benefit under 35 USC 119(a) of Korean Patent Application No. 10-2014-0193356 filed on Dec. 30, 2014, in the Korean Intellectual Property Office, the disclosure of which is incorporated herein by reference for all purposes.

### BACKGROUND

1. Field

The following description relates to an electronic component module and a manufacturing method thereof.

2. Description of Related Art

Demand for portable electronic devices has recently increased. In addition, the miniaturization and lightening of electronic component modules mounted in electronic products have been in demand. Particularly, such electronic component modules have been miniaturized and levels of performance thereof have been improved, such that the number of pins required for connection thereof to a main circuit board has increased.

According to the related art, in the case that an electronic component is mounted on one surface of an electronic component module, it may be difficult to secure a sufficient number of pins having a size capable of satisfying demand for miniaturization.

Further, in a case of a module formed to be elongated in a lengthwise direction, cracks may be generated in solders due to warpage. In order to protect an integrated circuit component mounted on a lower surface of a board, the entire electronic component mounted on the lower surface needs sealing, whereby efficiency is decreased in view of cost and maintenance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic component module is capable of preventing cracks from being generated in solders due to warpage and is secured by a sufficient number of pins by accommodating second electronic components in a cavity divided into a plurality of regions by using second and third boards in which bumps are formed on a double-sided mounting board, and a manufacturing method thereof.

In another general aspect, an electronic component module and manufacturing method including effectively protects an electronic component mounted on a board by only performing a sealing treatment on a region requiring sealing in a cavity divided into a plurality of regions by using second and third boards.

In another general aspect, an electronic component module including a first board; a plurality of first electronic components disposed on a first surface of the first board; a second board disposed on a second surface of the first board, opposite to the one surface, to form a cavity; a third board disposed on the second surface of the first board to divide the cavity into a plurality of regions; and a plurality of second electronic components disposed in the regions and disposed on the second surface of the first board. The second electronic component may include at least one integrated circuit component, and the electronic component module may further include a second sealing member enclosing a region in which the integrated circuit component is mounted among the plurality of regions.

According to another general aspect, a method of manufacturing an electronic component module including preparing a first board comprising mounting electrodes formed on an upper surface and lower surface of the first board; mounting at least one first electronic component on the upper surface of the first board; mounting at least one second electronic component on the lower surface of the first board; and bonding a second board to the lower surface of the first board to form a cavity and bonding a third board to the lower surface of the first board to divide the cavity into a plurality of regions. The method may further include forming a second sealing member enclosing at least one region among the plurality of regions.

Other features and aspects will be apparent from the following detailed description, the drawings, and the claims.

### BRIEF DESCRIPTION OF DRAWINGS

FIG. 1 is a perspective view illustrating an example of an electronic component module;

FIG. 2 is a perspective view illustrating a bottom surface of the electronic component module illustrated in FIG. 1;

FIG. 3 is a cross-sectional view illustrating an example of the electronic component module taken along line A-A′ of FIG. 1;

FIG. 4 is a cross-sectional view illustrating an example of the electronic component module taken along line A-A′ of FIG. 1;

FIG. 5 is an exploded perspective view of the electronic component module illustrated in FIG. 1; and

FIGS. 6 and 7 are flowcharts illustrating an example of a method of manufacturing an electronic component module.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless indicated otherwise, a statement that a first layer is “on” a second layer or a surface is to be interpreted as covering both a case where the first layer directly contacts the second layer or the surface, and a case where one or more other layers are disposed between the first layer and the second layer or the surface.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation,

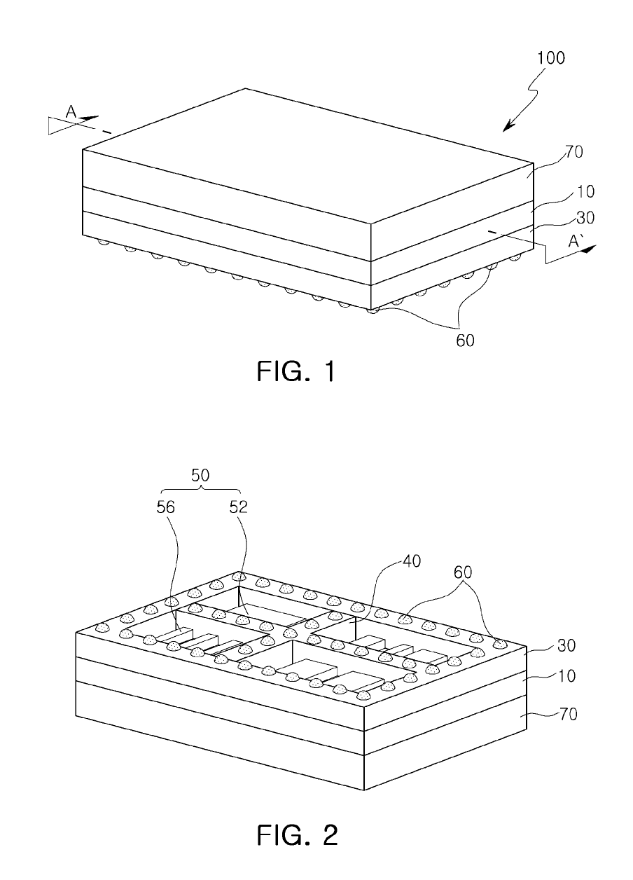

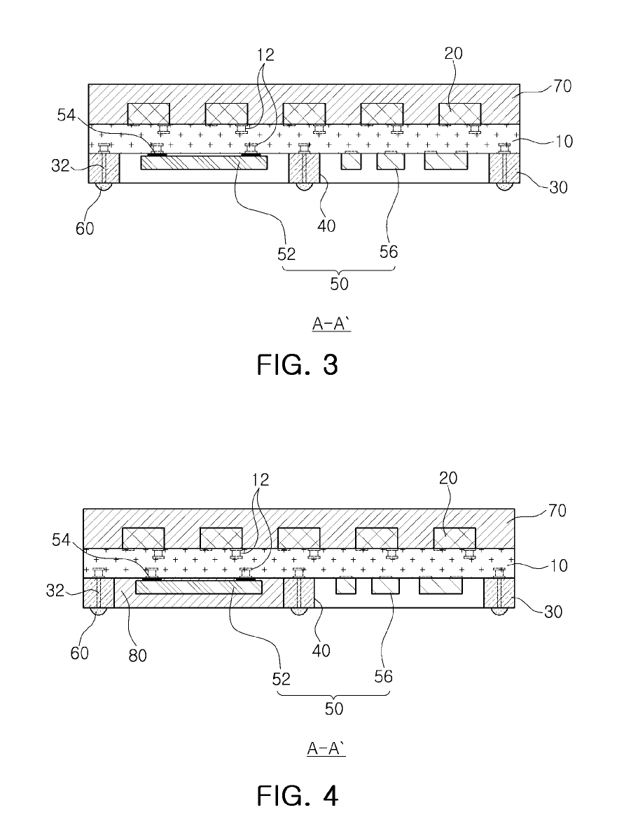

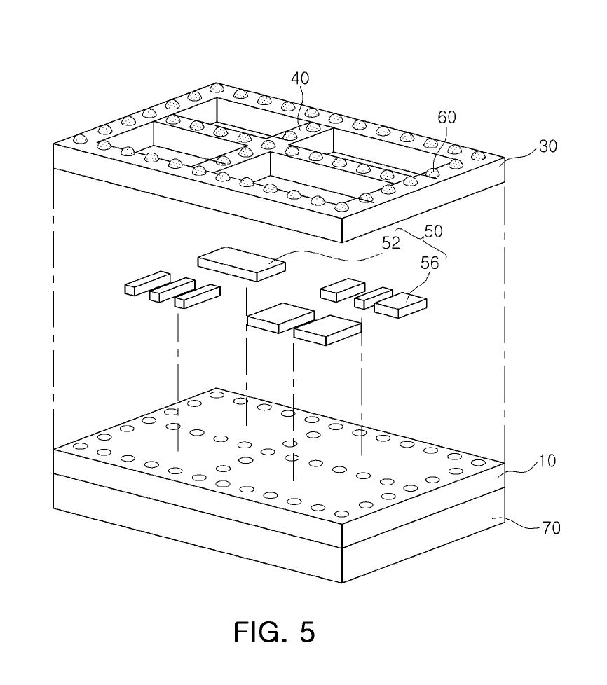

Referring to FIGS. 1 through 5, an electronic component module 100 includes a first board 10, a plurality of first electronic components 20, a second board 30, a third board 40, and a plurality of second electronic components 50. The electronic component module 100 further includes a first sealing member 70. The electronic component module 100 further includes a second sealing member 80.

The first to third boards 10, 30, and 40 may be ceramic boards. However, first to third boards 10, 30, and 40 are not limited thereto, and various kinds of boards (for example, printed circuit boards (PCBs), glass boards, silicon boards, flexible boards, and the like) may be used.

Upper and lower surfaces of the first board 10 include mounting electrodes 12 for mounting the first and second electronic components 20 and 50, or circuit patterns (not illustrated) for electrically connecting the electrodes or both. The lower surface of the first board 10 further includes pins 32 electrically connected to bumps 60 formed on the second and third boards 30 and 40.

The second board 30 is bonded to the lower surface of the first board 10 to form a cavity. For example, the second board 30 is formed as a tetragonal frame and is bonded to the lower surface of the first board 10 to form a cavity of which a lower surface is open.

The third board 40 is bonded to the lower surface of the first board 10 to divide the cavity formed by the second board 30 and the first board 10 into a plurality of regions. For example, the third board 40 may be formed in a linear bar shape and is bonded to the first board 10 to divide the cavity into two regions.

Alternatively, the third board 40 may be formed to have a ‘+’ shape and is bonded to the first board 10 to divide the cavity into four regions. In addition, if necessary, the third board 40 may be formed in various shapes such as an ‘L’ shape, a ‘T’ shape, and the like, to divide the cavity into a plurality of regions. At least one second electronic component 50 may be accommodated in each of the divided regions of the cavity. The second and third boards 30 and 40 may be formed integrally with each other.

The second and third boards 30 and 40 further include a plurality of connecting bumps 60, and the bumps 60 are electrically connected to the first board 10.

The first and second electronic components 20 and 50 may include various electronic elements such as a passive element and an active element, and all of the electronic elements may be used as the first and second electronic components 20 and 50 as long as the electronic elements are mounted on the first board 10. The first electronic components 20 are mounted on one surface of the first board 10, and the second electronic components 50 are mounted on the other surface of the first board 10. If necessary, the plurality of second electronic components 50 may be mounted in the region divided by the third board 40.

The second electronic components 50 may include a wafer level package (WLP)-type integrated circuit component 52 and a plurality of passive elements 56. A connection terminal 54 for electrically connecting the integrated circuit component 52 to the bump 60 of the second or third board 30 or 40 is formed on the first board 10. The connection terminal 54 may be formed in various forms such as in a form of an electrode pad, a bump, or a solder ball, as needed.

The first sealing member 70 is provided in order to safely protect the first electronic components 20 mounted on one surface of the first board 10 from external impacts. To this end, the first sealing member 70 is formed to enclose the entire upper surface of the first board 10 so that the first electronic components 20 mounted on one surface of the first board 10 are accommodated therein, thereby sealing the first electronic components 20 on the first board 10.

The second sealing member 80 may be formed in at least one region of the cavity divided into the plurality of regions by the third board 40 as illustrated in FIG. 4, thereby protecting the second electronic components 50 accommodated in the cavity from external impacts. The second sealing member 80 encloses the region so that the integrated circuit component 52 is accommodated therein, thereby sealing the integrated circuit component 52 on the first board 10.

The first and second sealing members 70 and 80 may be formed by a molding method. In order to form the first and second sealing members 70 and 80 using an epoxy molding compound (EMC), various methods such as a printing method, a spin-coating method, a jetting method, and others, may be used as needed.

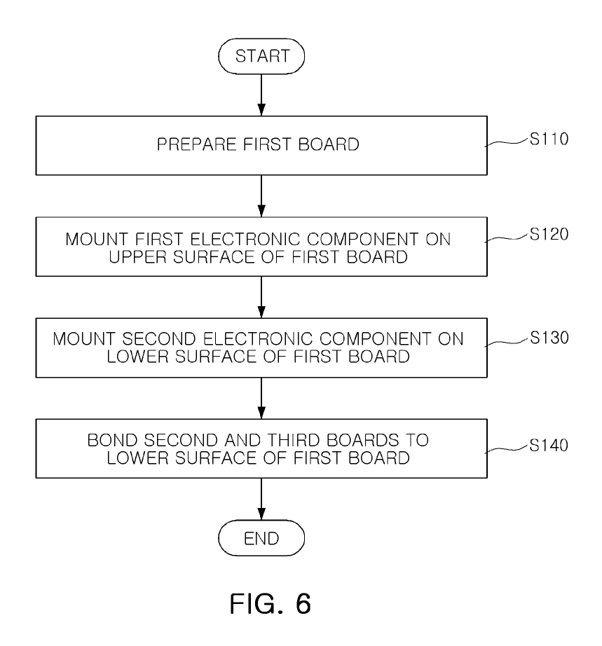

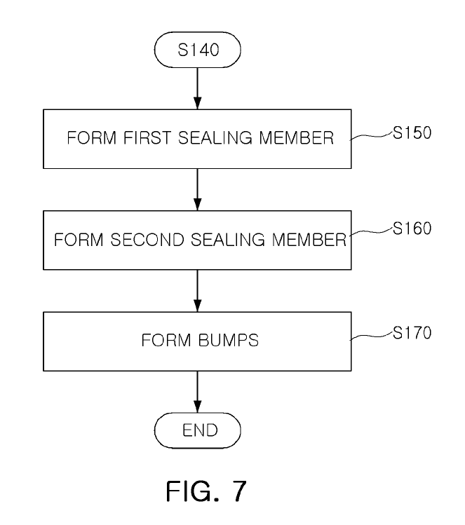

Hereinafter, a method of manufacturing an electronic component module according to an exemplary embodiment will be described. Referring to FIG. 6, in a manufacturing method of an electronic component module, a first board 10 having a first surface and a second surface opposite to the first surface, on which mounting electrodes 12 are formed is prepared (S110). For example, the first board 10 has mounting electrodes 12 formed on an upper surface of the board, and a lower surface of the board 10. Then, the first electronic components 20 are mounted on the upper surface of the first board 10 (S120), and second electronic components 50 are mounted on the lower surface of the first board 10 (S130). Here, the second electronic components 50 are disposed on the lower surface of the first board 10 to be accommodated in the cavity divided into a plurality of regions by second and third boards 30 and 40.

Next, the second and third boards 30 and 40 are bonded to the lower surface of the first board 10. Here, the second and third boards 30 and 40 may be formed integrally with each other, and the second and third boards 30 and 40 formed integrally with each other are simultaneously bonded to the first board 10.

The method of manufacturing an electronic component module further includes, after the bonding of the second and third boards 30 and 40 to the lower surface of the first board 10, forming a first sealing member 70 enclosing the first electronic components 20 on the first board 10 (S150) and forming a second sealing member 80 enclosing at least one region among the plurality of regions formed in the lower surface of the first board 10 (S160). The forming of the first sealing member (S150) and the forming of the second sealing member 80 (S160) may be sequentially or simultaneously performed, or the first sealing member 70 may be formed after the second sealing member 80 is formed.

The method of manufacturing an electronic component module further includes forming a plurality of bumps 60 on lower surfaces of the second and third boards 30 and 40 (S170). The electronic component module according to the present exemplary embodiment illustrated in FIGS. 1 through 4 may be manufacture by the process as described above. In the method of manufacturing an electronic component module according to the present exemplary embodiment as described above, a process sequence may be varied. For example, after the first electronic components 20 are mounted on the upper surface of the first board 10, the first sealing member 70 may be directly formed thereon, and while the second electronic components 50 are mounted on a lower portion of the first board 10, a connection terminal (a solder ball or the like) may be simultaneously formed.

As set forth above, the electronic component module prevents cracks from being generated in solders by warpage and secures a sufficient number of pins by accommodating the second electronic components in the cavity divided into the plurality of regions by using the second and third boards on which the bumps are formed. Further, the electronic components mounted on the board are effectively protected through a sealing treatment or the like, on only a particular region, of the plurality of regions of the cavity, requiring sealing by using second and third boards.

As a non-exhaustive example only, a terminal/device/unit as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic component module comprising:
a first board;
a plurality of first electronic components disposed on a first surface of the first board;
a second board disposed on a second surface of the first board, opposite to the one surface, to form a cavity;
a third board disposed on the second surface of the first board to divide the cavity into a plurality of regions; and
a plurality of second electronic components disposed in the regions and disposed on the second surface of the first board.

2. The electronic component module of claim 1, wherein the second and third boards comprise a plurality of connecting bumps, and
the bumps are electrically connected to the first board.

3. The electronic component module of claim 1, further comprising a first sealing member disposed on the first board configured to enclose the plurality of first electronic components.

4. The electronic component module of claim 1, wherein the second electronic components comprise an integrated circuit component disposed in one region of the plurality of regions, and
the electronic component module further comprises a second sealing member enclosing the one region in which the integrated circuit component is disposed.

5. The electronic component module of claim 1, wherein the second and third boards are integrally formed with each other.

6. The electronic component module of claim 1, wherein the first board comprises mounting electrodes on the first surface and the second surface.

7. A method of manufacturing an electronic component module, the method comprising:
preparing a first board comprising mounting electrodes formed on an upper surface and lower surface of the first board;
mounting at least one first electronic component on the upper surface of the first board;
mounting at least one second electronic component on the lower surface of the first board; and
bonding a second board to the lower surface of the first board to form a cavity and bonding a third board to the lower surface of the first board to divide the cavity into a plurality of regions.

8. The method of claim 6, further comprising forming a first sealing member enclosing the first electronic component on the first board.

9. The method of claim 6, further comprising forming a second sealing member enclosing at least one region among the plurality of regions.

10. The method of claim 6, further comprising forming a plurality of bumps on lower surfaces of the second and third boards.

11. An electronic module comprising:
a first board comprising a first surface and a second surface opposite to the first surface;
a second board disposed on the second surface, wherein the first board and the second board form a cavity;
a third board disposed on the second surface, wherein the third board separates the cavity into a plurality of regions;
a plurality of first electronic components disposed on the first surface; and
a plurality of second electronic components disposed in a region of the plurality of regions.
